(19) United States
(12) Patent Application Publication
(10) Pub. No.: US 2013/0049143 A1
(43) Pub. Date: Feb. 28, 2013

(54) RELEASE ACTIVATED THIN FILM GETTER

(71) Applicant: Jon B. Lasiter, Stockton, CA (US)

(72) Inventor: Jon B. Lasiter, Stockton, CA (US)

(73) Assignee: QUALCOMM MEMS TECHNOLOGIES, INC., San Diego, CA (US)

(21) Appl. No.: 13/219,431

(22) Filed: Aug. 26, 2011

(51) Int. Cl. H01L 29/84; H01L 21/50

(52) U.S. Cl. 257/415; 438/51; 257/E29.324; 257/E21.499

(57) ABSTRACT

This disclosure provides apparatuses, systems and methods for manufacturing electromechanical systems (EMS) devices having a means for removing and/or mitigating unwanted environmental stresses from within the device. In some implementations, an integrated getter layer that is exposed to an internal cavity of the electromechanical systems device can be configured to help remove and/or mitigate unwanted moisture from within an EMS device.

### TECHNICAL FIELD

This disclosure relates to electromechanical systems. More specifically, this disclosure relates to electromechanical systems with an integrated thin film getter.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography and/or other micromachining processes that etch away parts of substrates and/or deposited material layers or that add layers to form electrical and electromechanical systems devices.

EMS devices can contain fragile movable parts that are packaged in a clean and stable environment. Encapsulation of the EMS device is possible using certain proven ceramic or metal-can packages, but the cost can be high and can pose many technological complexities. For instance, standard wafer sawing is not typically used, as it may destroy the EMS device. It follows that packaging is carried out during wafer processing, prior to die singulation (wafer dicing). This packaging process is referred to as wafer-level packaging. The wafer-level packaging creates an on-wafer device scale enclosure around, or sealed cavity for, the EMS device, and serves as a first protective interface. Once the device is wafer-level packed, the EMS product wafers can be diced without great danger of breaking the EMS device. In addition to low-cost fabrication process and physical protection, the wafer-level package should be strong, equipped with electrical feed-throughs and be near hermetic or hermetic, preventing or reducing any particles and moisture from migrating into the region under the freely moving EMS devices.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of manufacturing an electromechanical systems device. The method can include providing a substrate having a getter layer and forming an electromechanical systems device above the getter layer. The electromechanical systems device can have an internal cavity exposed to the getter layer. The electromechanical systems device can have a movable layer within the internal cavity. The method can further include depositing a first sacrificial layer on the getter layer and removing a portion of the first sacrificial layer to expose the getter layer. The method can be performed using in situ deposition or a combination of in situ deposition and sequential deposition. The getter layer can include lanthanum (La), titanium (Ti), zirconium (Zr), niobium (Nb), tantalum (Ta), vanadium (V), aluminum (Al) or alloys thereof. The deposition of the getter layer and the first sacrificial layer can use techniques such as physical vapor deposition, plasma-enhanced chemical vapor deposition, thermal chemical vapor deposition, atomic layer deposition or spin-coating.

Another innovative aspect of the subject matter described in this disclosure can be implemented in an electromechanical system device package. The electromechanical system device package includes a substrate and one or more electromechanical system devices disposed on the substrate. The electromechanical system device package also includes a thin film getter disposed within an internal cavity. In the internal cavity of the device package, the getter layer contacts the substrate. Additionally, the device package includes movable layers that are suspended in the internal cavity. The movable layers may optionally be configured to contact a conductor upon the application of a voltage difference.

Another innovative aspect of the subject matter described in this disclosure can be implemented in an electromechanical systems device. The device can have a substrate, a means for absorbing water vapor or environmental gases where the means is in contact with the substrate, and one or more electromechanical systems device layers deposited above the substrate. The electromechanical systems device layers form a cavity that is exposed to the absorbing means. The absorbing means can be a thin film getter. The electromechanical systems device can have movable layers that are suspended in the cavity.

Details of one or more implementations of the subject matter described in this specification are set forth in the accompanying drawings and the description below. Other features, aspects and advantages will become apparent from the description, the drawings and the claims. Note that the relative dimensions of the following figures may not be drawn to scale.

### BRIEF DESCRIPTION OF THE DRAWINGS

FIG. 1 shows a cross-sectional view of an example of an electromechanical systems device having a getter layer.

FIGS. 2A and 2B show examples of flow diagrams illustrating manufacturing processes for an electromechanical systems device.

FIGS. 3A-3J show cross-sectional schematic illustrations of various states of making an electromechanical systems device having a getter layer.

FIG. 4 shows a cross-sectional schematic illustration of a contact electromechanical systems device.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth) devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

EMS devices are sensitive to environmental conditions such as humidity, as well as physical conditions related to manufacturing and packing. Moreover, the fabrication of EMS devices often results in the trapping of gases and/or moisture within the devices. In hermetically sealed EMS with moving parts, for example, the degradation of vacuum or inert atmosphere may affect the proper working conditions of the EMS device.

Some implementations relate to an electromechanical systems device that includes an integrated getter material within the device to remove trace gases or moisture through chemical reactions. In some implementations, one or more integrated layers of a getter material are enclosed within the interior of an electromechanical systems device. In some implementations, the getter material is deposited as a thin film within a cavity of the electromechanical systems device. In some other implementations, the getter material is deposited as a thin film below, above or adjacent a cavity of the electromechanical systems device. Other implementations relate to methods of manufacturing such devices having integrated getter material.

An example of a suitable electromechanical systems (EMS) device is a microelectromechanical systems (MEMS) device. In some implementations, the MEMS device can be non-contact MEMS devices such as resonators, filters and other passive electronic devices. Such devices may use beams that are anchored or fixed at one or multiple ends allowing for the free suspension in a cavity of the beams or actuation of the beams via electrical pulses controlled by control circuits under the direction of firmware instructions. The cavity in which the MEMS device is housed is typically enclosed to protect the MEMS device from direct contact and unwanted environmental stresses, such as moisture and/or gases. Cavity down caps and thin film caps (TF-cap) are two known methods commonly used to enclose an open cavity where MEMS structures reside. In the case of the cavity down cap, the cap is attached with a sealant on the device substrate to form an enclosed housing for MEMS devices. However, such methods do not actively mitigate unwanted environmental stresses from within the electromechanical systems device.

In another implementation, the EMS device is a contact MEMS device. Such devices are suitable for the construction of switches and related devices, examples of which rely upon contact to generate signals. One example of a switch is an electrostatic switch in which the switch is operated by an electrostatic charge. Such switches and related devices can control electrical, mechanical or optical signal flow. Thus, such switches and related devices have applications in telecommunications, such as DSL switch matrices, cell phones, Automated Testing Equipment and systems that use low-cost switches and/or low-cost, high density switch arrays.

Examples of contact EMS switch designs include, but are not limited to, cantilevered beam/plate designs, membrane supported designs, multiple-support beam/plate geometry designs, single pole/single throw, single pole/double throw, single pole changeover, double pole/double throw and double pole changeover. In the case of cantilevered beams, these designs include a movable, bi-material beam. Some designs further include a layer of dielectric material and/or a layer of metal. Such layers can afford additional structure and/or support to the design. In some implementations, the dielectric material is fixed at one end of the device with respect to the substrate and provides structural support for the beam/plate. In some designs, the metal layer is attached on the underside of the dielectric material and forms a movable electrode and a movable contact. In some implementations, the metal layer can be part of the anchor. In such implementations, the movable beam/plate is actuated in a direction toward the intended contact by the application of a voltage difference across the electrode and another electrode attached to the surface of the intended contact. The application of a voltage difference to the two electrodes creates an electrostatic field, which pulls the beam/plate towards the intended contact. The beam/plate and intended contact are each separated by a gap when no voltage difference is applied, thereby affording the switch design an “open” position. When a voltage difference is applied, however, the beam/plate is pulled to the intended contact and the contacts can make an electrical connection, thereby affording the switch design a “closed” position.

One advantage of a device as described herein is that such devices can remove and/or sequester unwanted environmental gasses present within the device during and after fabrication. Another advantage of such a device is that an integrated getter layer can act as an absorbing and adsorbing means to remove gases and/or moisture within a device package to maintain an internal vacuum. The maintenance of a vacuum environment within the device package can be useful because device performance, quality factor or Q value, package integrity and longevity/useful life can be improved compared to a device that is not maintained in a vacuum or near vacuum environment. One other advantage of implementations of manufacturing methods described herein is that integrating the getter layer into an electromechanical systems device can render further steps to measure or remove gas and/or moisture from the device unnecessary.

In some implementations, it is useful to package EMS devices at the wafer level. Conventional wafer-level chip scale packages (WLCSP) combine the chip scale package advantages of small size and ease of handling with an efficient production approach based on batch packaging at wafer level (such as simultaneous packaging of multiple devices at the same time on a wafer). In this type of processing, the packages are created directly on the wafer, before the wafers are sawn or otherwise diced into individual units. In creating the package, additional layers of material, such as a thin film cap, may be deposited over the active surface of the die.

Wafer-level packaging with a protective cavity adds mechanical protection, beginning at the wafer level, for devices with fragile surface features, such as MEMS, optoelectronics and sensors. Some of these devices function best in a controlled atmosphere in the cavity, while others function best in a vacuum. Wafer-level packaging of vacuum cavities can help reduce costs associated with simultaneously sealing an entire wafer of cavities in vacuum. This eliminates the manufacturing inefficiencies and the costs of an individual “pump down and pinch off” approach for metal or ceramic vacuum packages. Incorporating a means for maintaining a vacuum within the cavity, such as a getter material, that does not interfere with the MEMS device's operation can provide additional protection for devices with fragile surface features and can further aid the functioning of MEMS devices. In various implementations, the devices can be packaged using wafer-level packaging or a method other than wafer-level packaging.

FIG. 1 shows a cross-sectional view of one type of an electromechanical systems device having a getter layer. In FIG. 1, an electromechanical systems device 100 has one or more substrate layers 110. For improved clarity, the substrate layer(s) 110 have been drawn thinner than the other layers and features shown. A getter layer 120 contacts the one or more substrate layers 110 while being exposed on one or more surfaces to a cavity 170. Suitable materials useful for preparing a getter layer are described in more detail below.

The electromechanical systems device 100 includes one or more electromechanical systems device layers, such as layers 130 and 140. The electromechanical systems device layers are suspended above a cavity 170 and below a cavity 180. The electromechanical systems device layers also are separated by a gap 190. Thus, FIG. 1 is illustrative of a non-contact electromechanical systems device. The cavity 180 is bounded by a hermeticity layer 150, and a sealant material 160 that plugs a release opening in the hermeticity layer 150.

As illustrated in FIG. 1, the getter layer 120 is exposed to the cavities 170, 180 and the gap 190 such that the getter layer 120 may absorb and/or adsorb gases and/or moisture present when the device is sealed. This can reduce the chance of stiction caused by gases and/or moisture present within the device. In addition, in some implementations the getter layer 120 is configured to absorb and/or adsorb gases and/or moisture within the device to effectively maintain a vacuum within the cavities 170, 180 and the gap 190, and can furthermore absorb and/or adsorb gases and/or moisture that diffuse over time into the cavities 170, 180 and gap 190.

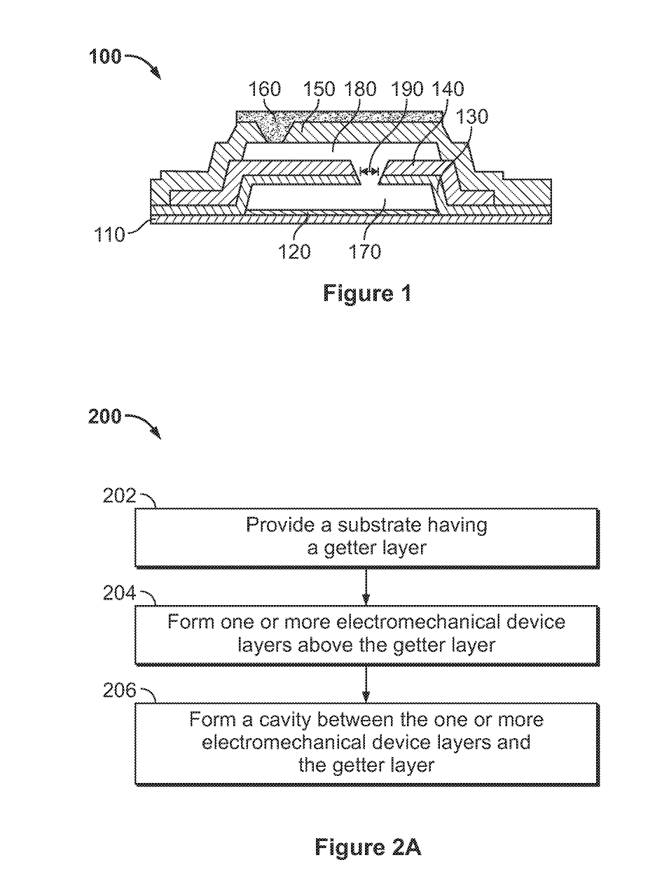

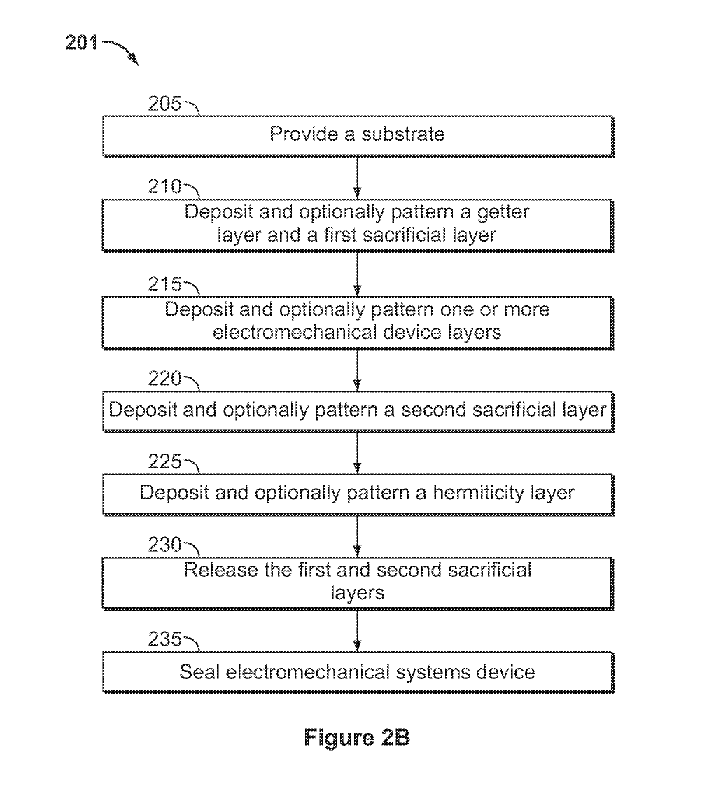

FIGS. 2A and 2B show examples of flow diagrams illustrating manufacturing processes for an electromechanical systems device. With reference to FIG. 2A, a process 200 begins at a block 202 by providing a substrate having a getter layer. The getter layer is one means for absorbing and/or adsorbing gases and/or moisture. Examples of substrate and getter materials are further described below.

After the substrate having the getter layer is provided at block 202, the process 200 continues to a block 204 in which one or more electromechanical device layers are formed above the getter layer. The process 200 then continues to a block 206 in which a cavity is formed between the one or more electromechanical device layers and the getter layer. In some implementations, a cavity is formed by depositing a sacrificial layer between the one or more electromechanical device layers and the getter layer, followed by releasing the sacrificial layer to form the cavity. Such a process is further described in relation to FIG. 2B.

With reference to FIG. 2B, a process 201 begins at a block 205 with the provision of a substrate. The process 201 continues to a block 210 in which a first sacrificial layer and a getter layer are deposited and optionally patterned. Formation of the first sacrificial layer over the getter layer can involve known methods of deposition and optional patterning. Examples of materials for the sacrificial layers are further described below.

The process 201 continues to a block 215 in which one or more electromechanical systems device layers are deposited and optionally patterned over the first sacrificial layer. Formation of the one or more electromechanical systems device layers over the first sacrificial layer can involve known methods of deposition and optional patterning. While patterning after deposition can be optional in some implementations, a person having ordinary skill in the art will readily understand that patterning of the first sacrificial layer may be performed after further layers are deposited over the first sacrificial layer. Similarly, when patterning may be referred to as optional, it is understood that it can be optional at that block, and may in certain implementations be performed in subsequent blocks. The step performed at block 215 may be repeated in some implementations to form multiple electromechanical systems device layers over the first sacrificial layer.

The process 201 then continues to a block 220 to deposit and optionally pattern a second sacrificial layer over the one or more previously deposited electromechanical systems device layers. After the second sacrificial layer has been deposited, the process 201 continues to a block 225 in which a hermeticity layer is deposited and optionally patterned. The formation of the hermeticity layer over the second sacrificial layer can involve known methods of deposition and optional patterning. Examples of materials for the hermeticity layer are further described below.

The process 201 then continues to a block 230 in which the first and second sacrificial layers are released in order to form internal cavities within the electromechanical systems device. Release can be accomplished using any technique known to remove the sacrificial layers. For example, removal can be accomplished using light, release chemicals or physical force. The release can be performed using a chemical wet or dry etch. The etch process used can be chosen to selectively etch or have a high etch rate for the sacrificial layers and have a lower etch rate for one or more of the substrate layer materials and/or the getter layer materials. In some implementations the etch process may partially erode the deposited getter layer to increase the surface area of the getter layer and consequently improve the layer's ability to absorb and/or adsorb gases and/or moisture. In some implementations, the etchant process uses xenon difluoride (XeF₂). However, a person of ordinary skill in the art will readily understand that any process or material capable of sublimating and/or removing the sacrificial layer may be utilized.

The process 201 then continues to a block 235 in which the electromechanical systems device is sealed. Sealing can prevent and/or lessen the infusion of gases and/or moisture within the electromechanical systems device and can provide, in different implementations, a hermetic or near hermetic seal. Many suitable sealing materials are known to a person of ordinary skill in the art. Examples of sealing materials are further described below.

In some implementations, the processes 200 and 201 utilize sequential deposition of one or more layers. “Sequential deposition,” is used herein to refer to a deposition process that involves removing the product of a first deposition from an evacuated environment prior to subjecting the product to a second deposition. An example of sequential deposition can be depositing a layer of material onto a substrate under vacuum, removing the substrate from the vacuum environment, and then depositing a second layer of material to the product. The deposition of the second layer may optionally be performed in a vacuum environment. In some implementations, at least one sequential deposition is performed in process 201 for one or more of blocks 205-225.

In some implementations utilizing one or more sequential depositions, additional actions may be taken for removing any material from the surface of the getter layer prior to additional depositions or use in a device. In some implementations, the material removed by etching includes getter layer material having reacted with atmospheric gases and/or moisture. Alternatively, the material can be a native oxide or a metal oxide, such as the metal oxide of one or more of the metals selected from those listed below as getter layer material. The etching or removal of the material can be accomplished by, for example, energetic etching or solution sputter etching. In the removal process, some getter layer material also may be removed. In some implementations, removal of material from the surface of the getter layer activates the getter layer for reaction with atmospheric gases and/or moisture. In some other implementations, the getter layer is activated without removal of material from the surface of the getter layer. In such implementations, the getter layer can be activated by thermal and/or chemical treatment.

In some implementations, the processes 200 and 201 can utilize in situ deposition of one or more layers. It is understood that during “in situ deposition,” after a first deposition on a substrate under vacuum, the substrate remains in an evacuated environment until a second layer of material is deposited. An example of in situ deposition is depositing a first layer of material, maintaining the product of the first deposition under vacuum, and then depositing a second layer of material. Such a process can use a cluster tool, but it is not limited to such a tool.

When deciding between deposition methods, one consideration for using in situ deposition over sequential deposition is that in situ deposition can maintain the deposited getter layer in an environment free of atmospheric gases and/or moisture. In various implementations, one or more of the blocks 210-225 can include in situ deposition. In some implementations, however, at least one deposition is sequential.

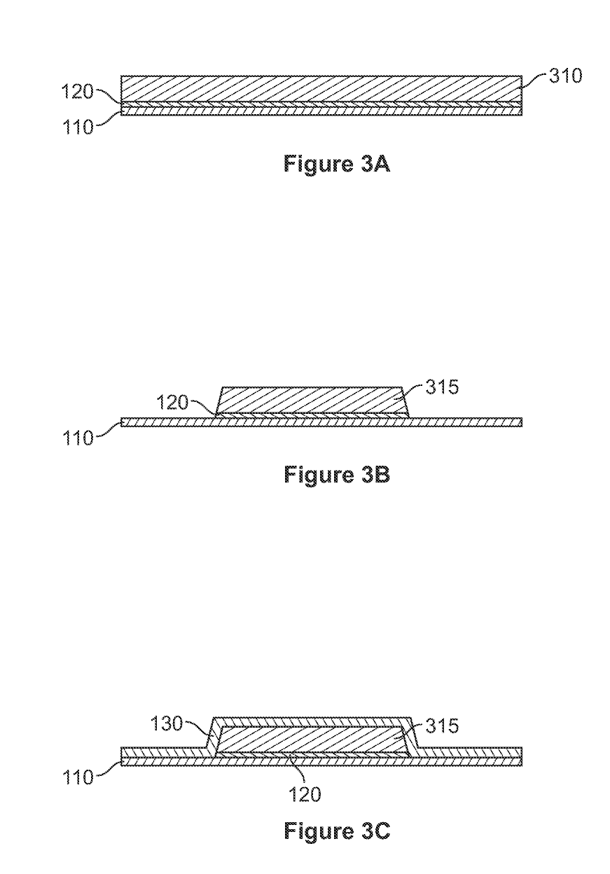

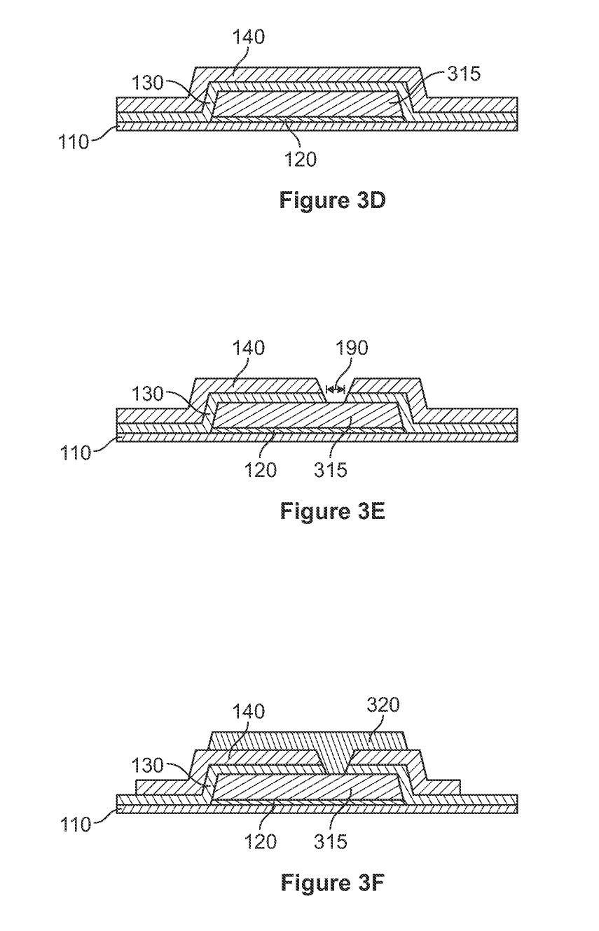

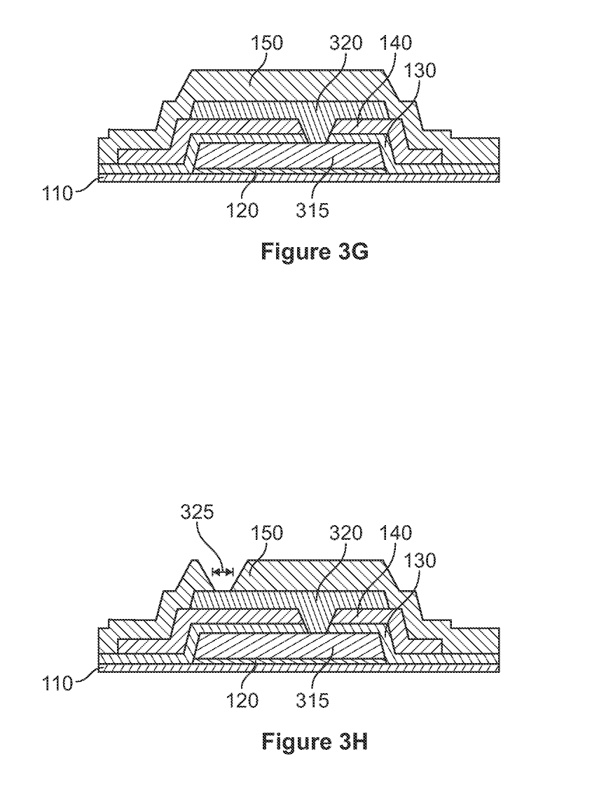

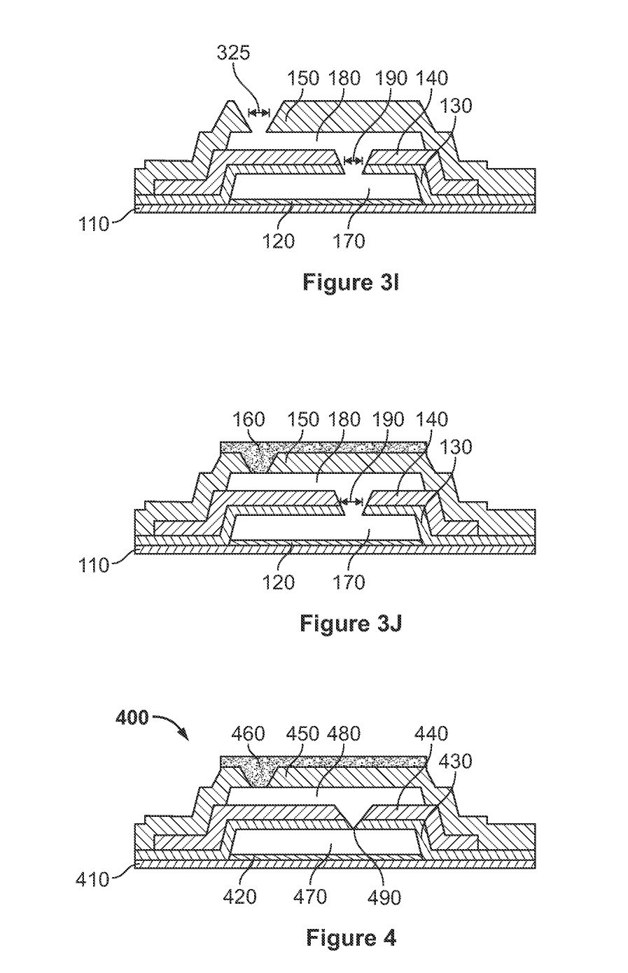

FIGS. 3A-3J show cross-sectional schematic illustrations of various states of manufacturing an electromechanical systems device having a getter layer. FIG. 3A illustrates an early stage of a process for making an electromechanical systems device in which a first sacrificial layer 310 is formed over a getter layer 120 and a substrate 110. In some implementations, the substrate 110 is glass; the sacrificial layer 310 is a material capable of being sublimated with xenon difluoride (XeF₂); and the getter layer 120 is a lanthanum-titanium-vanadium alloy (LaTiV). Optionally, one or more sacrificial layers, getter layers and/or substrates may be used.

FIG. 3B illustrates the patterning of the example illustrated in FIG. 3A. In FIG. 3B, both the getter layer 120 and the first sacrificial layer 315 are depicted as patterned. In some implementations, only the first sacrificial layer or the one or more sacrificial layers are patterned. When more than one sacrificial layer is used, select portions of the individual sacrificial layers may be patterned. As a non-limiting example, if three sacrificial layers are deposited upon each other, any one or all of the three sacrificial layers can be patterned.

FIG. 3C illustrates the formation of a first electromechanical systems device layer 130 over the sacrificial layer 315. FIG. 3D illustrates the formation of a second electromechanical systems device layer 140 deposited over the device layer 130. It is understood that the device layers 130 and/or 140 may optionally be individually patterned prior to forming additional layers over the layers 130 and/or 140, or alternatively, the device layers 130 and/or 140 may be patterned after additional layers are formed. Similarly, when patterning is described as optional, it is noted that it may be optional at a certain stage in the process and may, in some implementations, be performed subsequently, for example, after the deposition of additional layers. Moreover, additional device layers may be formed over the device layer 140, with optional individual patterning prior to subsequent layer formation.

FIG. 3E illustrates the patterning of both of the device layers 130 and 140 to provide a gap 190 that interrupts the continuity of the device layers. In some implementations, the gap 190 is about 0.5 μm. In other implementations, the gap 190 is greater than about 0.5 μm. In some implementations, the gap 190 is about 0.1 μm, 0.2 μm, 0.3 μm, 0.4 μm, 0.5 μm, 0.6 μm, 0.7 μm, 0.8 μm, 0.9 μm, 1.0 μm, or gap 190 is a range defined by any two of the previously identified dimensions. A person having ordinary skill in the art will understand that the size of gap 190 will affect the release rate of the sacrificial layer 315. A person having ordinary skill in the art will also understand that as the size of the gap 190 increases, the rate of release of the sacrificial layer 315 will increase.

FIG. 3F illustrates the formation of a second sacrificial layer 320 over the device layers 130 and 140. The sacrificial layer 320 fills the gap 190 such that the first sacrificial layer 315 is in contact with the second sacrificial layer 320. Optionally, the sacrificial layer 320 may be patterned prior to additional layer formation.

FIG. 3G illustrates the formation of a hermeticity layer 150 over the sacrificial layer 320. Optionally, one or more hermeticity layers may be used and individually patterned prior to forming additional layers or conducting subsequent manufacturing processes and/or steps.

FIG. 3H illustrates the patterning of the hermeticity layer 150 to form a gap 325 in the hermeticity layer that exposes the sacrificial layer 320. In some implementations, pattering the hermeticity layer 150 results in two or more gaps that expose the sacrificial layer 320. In some implementations, the gap 325 is about 0.5 μm. In other implementations, the gap 325 is greater than about 0.5 μm. In some implementations, the gap 190 is about 0.1 μm, 0.2 μm, 0.3 μm, 0.4 μm, 0.5 μm, 0.6 μm, 0.7 μm, 0.8 μm, 0.9 μm, 1.0 μm, or gap 190 is a range defined by any two of the previously identified dimensions. A person having ordinary skill in the art will understand that the size of gap 325 will affect the release rate of the sacrificial layers 315 and 320. A person having ordinary skill in the art will also understand that as the size of the gap 325 increases, the rate of release of the sacrificial layers 315 and 320 will increase.

FIG. 3I illustrates the release of the second sacrificial layer 320 and the first sacrificial layer 315, resulting in the formation of the cavities 180, 170 and gap 190. FIG. 3J illustrates the sealing of the gap 325 with a sealant material 160. Examples of suitable sealant materials are described below.

Various sealing procedures and materials can be utilized, as further discussed below. As a non-limiting example, chemical vapor deposition of silicon oxide, silicon oxynitride, silicon nitride; alumina (deposited, for example, by atomic layer deposition (ALD)); and/or combinations of these materials and deposition processes can be used for the sealing process. Alternatively, the sealing process can utilize the application of a metal above the hermeticity layer.

In some implementations, sealing affords a hermetic seal. In some implementations, sealing affords a near hermetic seal. Optionally, sealant material 160 may be patterned prior to additional manufacturing processes and/or steps. As FIG. 3J illustrates, the device layers 130 and 140 are suspended above the getter layer 120 via the cavity 170 and below the hermeticity layer 150 via the cavity 180.

A person having ordinary skill in the art will readily recognize that the process described above may include the deposition and/or patterning of one or more sub-layers. In some implementations, the formation of the substrate layer, getter layer, electromechanical systems device layers, sacrificial layers, hermeticity layer and sealant optionally include the deposition and/or patterning of one or more sub-layers. A person having ordinary skill in the art will also readily recognize that the processes described above may include the deposition and/or patterning of intervening layers and/or sub-layers between the described layers. In some implementations, the deposition and/or patterning of the substrate layer or sub-layers, the getter layer or sub-layers, the electromechanical systems device layers or sub-layers, the sacrificial layers or sub-layers, the hermeticity layer or sub-layers and the sealant layer or sub-layers optionally include the deposition and/or patterning of one or more intervening layers. In various implementations, the intervening layers can be conductive or non-conductive material. In some implementations, the intervening layers are additional getter layers. In some implementations one or more getter layers are deposited both above and below the electromechanical systems device layers.

As noted above, some deposition processes discussed in relation to FIGS. 2 and 3A-3J may be in situ deposition processes. By using in situ deposition in some implementations, the deposited getter layer can be maintained in an environment free of atmospheric gases and/or moisture. Such maintenance can help keep the surface of the getter layer free from reacting with atmospheric gases and/or moisture prior to incorporation in a device. Such maintenance can also keep the surface of the getter layer from deactivating and/or reducing its activity prior to incorporation in a device. Thus, in situ deposition can reduce additional processing steps that may be needed to activate the getter layer.

FIG. 4 shows a cross-sectional schematic illustration of a contact electromechanical systems device. Such a device can be manufactured according to the description of the process 200 above and the illustration of FIG. 2. In FIG. 4, an electromechanical systems device 400 has a substrate layer 410 and includes a getter layer 420 that is configured to contact the substrate layer 410 while being exposed on one or more surfaces to a cavity 470. For improved clarity, the substrate layer 410 has been drawn thinner than the other layers and features shown. The substrate layer 410 and getter layer 420 can include materials as discussed above in reference to FIG. 1 and further discussed below.

As illustrated, the device 400 includes electromechanical systems device layers 430 and 440. The electromechanical systems device layers 430 and 440 are suspended above the cavity 470 and below a cavity 480. The cavity 480 is bounded by a hermeticity layer 450, and the hermeticity layer 450 is plugged by a sealant material 460. In some implementations, the sealant material 460 can afford a hermetic seal for the cavities 470 and 480. In some other implementations, the sealant material 460 can afford a near hermetic seal for the cavities 470 and 480. The electromechanical systems device layers 430 and 440, hermeticity layer 450 and sealant material 460 can include materials as discussed above in reference to FIG. 1 and further discussed below.

In some implementations, application of a voltage difference across the gap 190 (represented in FIG. 1) results in closure of the gap 190 and contact between the layers 430 and 440 as shown in FIG. 4. Thus, in the absence of a voltage difference, the gap 190 from FIG. 1 can illustrate a switch design in an “open” position. Similarly, in the presence of a voltage difference, the gap 190 from FIG. 1 closes and the layers 130 and 140 that were previously separated in the absence of a voltage difference now come into contact, represented in FIG. 4 by the layers 430 and 440 and the contact 490. Consequently, the voltage difference makes a contact between the previously separated layers and provides an electrical connection. The electrical connection affords the switch design a “closed” position and allows a signal to proceed through the contacting layer(s). Moreover, intervening layers can be included in the switch design to serve as the contact to close the switch.

A person having ordinary skill in the art will readily recognize that the manufacturing methods described above can afford switch designs that differ from the above described designs. For example, a first voltage difference can be applied across the layer 440 and the layer 450, in which case separation of the layers 440 and 450 afford the switch an “open” position. Application of a second voltage difference across the layers 440 and 450 can move the layer 440 into contact with the layer 450 to “close” the switch design. Similarly, a first voltage difference can be applied across the layer 430 and the layer 420, in which case separation of the layers 430 and 420 afford the switch an “open” position. Application of a second voltage difference across the layers 430 and 420 can move the layer 430 into contact with the layer 420 to “close” the switch design. In some implementations voltage differences can be applied across one or more of layers 130 and/or 140 and one or more of layers 420 and/or 450. In some implementations, the first voltage difference can be zero. In other implementations, the potential difference can be greater than about 1.0 volts. In some implementations, for example, a 10 volt potential difference can cause a movable layer to deform from the relaxed state to the actuated state. However, when the voltage is reduced from that value, the movable layer maintains its state as the voltage drops back below 10 volts. In some implementations, there is a range of voltage, about 3 to 7 volts, in which the device is stable in either the relaxed or actuated state.

The above described switch designs presuppose the tailoring of the size of the cavities 470, 480 and the gap 490 such that the movable layer(s) can make the intended contact. Additionally, switch designs can utilize thermal expansion coefficients to afford a contact that results in a “closed” position of a thermally controlled switch. When switch designs rely, in whole or in part, upon thermal expansion coefficients, a person of ordinary skill in the art will readily understand that the distance of the gap 490 and the size of the cavities 470 and 480 can determine the materials used in the device.

The getter layer 420 as described in FIG. 4 can be exposed to the cavities 470, 480 and the gap 490 such that the getter layer 420 may absorb and/or adsorb gases and/or moisture present when the device is sealed. This can reduce the chance of stiction caused by gases and/or moisture present within the device when compared to a device without the getter layer 420. For contact EMS devices, moisture inside the sealed device can result in unwanted contact during operation or stiction in a “closed” position of the switch. The getter layer 420 can reduce these risks compared to an EMS device without the getter layer 420, thereby improving accurate transmission of signals within the switch. Furthermore, by absorbing and/or adsorbing gases and/or moisture, the getter layer 420 can prevent the gases and/or moisture from reacting with internal components of the device, thereby reducing degradation of device components compared to a device without the getter layer 420 and hence contributing to the extension the device's longevity/useful life.

Substrate (such as substrate 410 in FIG. 4) may be any substance capable of having electromechanical systems devices, including MEMS devices, built upon it. Such substances include, but are not limited to, glass, plastic, metal, ceramic, carbon and/or polymers. In some implementations, the substrate can include more than one layer of material.

Some implementations include a means for absorbing gases and/or moisture. Some implementations include a means for adsorbing gases and/or moisture. Some implementations have a gas and/or moisture sorption means such that can both adsorb and absorb moisture and/or gases. Such gases include, but are not limited to, nitrogen (N₂), oxygen (O₂), carbon dioxide (CO₂), neon (Ne), helium (He), methane (CH₄), ethane (C₂H₆), krypton (Kr), hydrogen (H₂), nitrous oxide (NO), carbon monoxide (CO), xenon (Xe), ozone (O₃), nitrogen dioxide (NO₂), iodine (I₂), ammonia (NH₃), natural gas and other gaseous hydrocarbons and/or water vapor (H₂O). In some implementations, the gases are those that can affect the performance of the electromechanical device, such as O₂, H₂, and water vapor. In some implementations, the gases are atmospheric gases. In some implementations, the gases are residual gases that were present when the implementation was fabricated. In some implementations, the gases are reactive with materials present in the device. In some implementations, the gases are non-reactive with materials present in the device. In some implementations, the gases are reactive ions, for example, reactive ions of environmental gases. In some implementations, the means for absorbing and/or adsorbing gases or moisture involves a chemical reaction for the absorbing and/or adsorbing function. In some implementations, the means for absorbing and/or adsorbing gases or moisture is permanent. In some other implementations, the means for absorbing and/or adsorbing gases or moisture is reversible.

One means for absorbing and/or adsorbing gases or moisture in a device is a getter material. A getter material is a material that includes in an intrinsic manner and/or by virtue of its microscopic morphology, absorbent and/or adsorbent properties vis-a-vis gaseous molecules. Consequently, getter materials can form a chemical pump when the getter material is arranged in a closed environment. In some implementations, the getter material is a moisture-type getter material including, but not limited to, a metal oxide and/or a zeolite. In some implementations, the getter material is a particle-type getter material. Alternatively, a combination of getter material types may be used.

The getter material in the described implementations may include any getter material such as titanium (Ti) and/or zirconium (Zr) and/or hafnium (Hf) and/or aluminum (Al) and/or barium (Ba) and/or cerium (Ce) and/or chromium (Cr) and/or cobalt (Co) and/or iron (Fe) and/or magnesium (Mg) and/or manganese (Mn) and/or molybdenum (Mo) and/or niobium (Nb) and/or tantalum (Ta) and/or thallium (Tl) and/or vanadium (V) and/or tungsten (W) and/or calcium (Ca) and/or sodium (Na) and/or strontium (Sr) and/or cesium (Cs) and/or phosphorus (P) and/or any other material that can have gaseous absorption properties. As mentioned previously, the getter material can be made of LaTiV. In some other implementations the getter material is made of Cr, cesium (Cs), lanthanum (La), titanium (Ti), vanadium (V), a combination of one or more of Cr, Cs, La, Ti and V, or other similar material that is configured to prevent moisture damage and/or is capable of absorbing and/or adsorbing gases. In some implementations, the getter layer is made of more than one getter material. A person of ordinary skill in the art will understand that many materials can be combined in many different ratios, and yet the materials can still function as getter materials.

Deposition of the getter material may be carried out using deposition techniques such as physical vapor deposition (PVD, e.g., sputtering), plasma-enhanced chemical vapor deposition (PECVD), thermal chemical vapor deposition (thermal CVD), atomic layer deposition (ALD) or spin-coating.

In some implementations, the thickness of the getter layer (such as getter layer 420 in FIG. 4) is about 10 Å to about 1 μm. For example, the thickness of the getter layer can be about 1 nm to about 100 nm, about 5 nm to about 100 nm, about 10 nm to about 75 nm, about 20 nm to about 50 nm, about 25 nm to about 35 nm or around 30 nm. In some implementations, the thickness of the getter layer is dependent upon the material(s) involved.

Sacrificial layers (such as first sacrificial layer 315 and second sacrificial layer 320 in FIG. 3F) can include any sacrificial material that can be selectively removed in the presence of other materials. In some implementations, sacrificial materials include photosensitive materials. In some implementations, sacrificial materials include etchable materials. In some implementations, the sacrificial material includes a XeF₂-etchable material. In some implementations, the XeF₂-etchable material includes Mo or amorphous silicon (a-Si), in any desired thickness. In some implementations, the sacrificial materials include germanium (Ge), W or a material that can be sublimated with fluorine.

Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), atomic layer deposition (ALD), lamination or spin-coating.

A person having ordinary skill in the art will readily recognize that the thickness of the sacrificial layers can be related to the size of cavities within the device. In some implementations, the thicknesses of the sacrificial layers are about 100 Å to about 10 μm. For example, the thickness of the sacrificial layer can be about 10 nm to about 1 μm, about 10 nm to about 500 nm, about 50 nm to about 250 nm, about 75 nm to about 150 nm, about 100 nm to about 125 nm, about 100 Å, around 1 μm or around 10 μm. In some implementations, the thickness of the sacrificial layers is dependent upon the material(s) involved. In some implementations, the thicknesses of two or more sacrificial layers are the same. In some implementations, the thicknesses of two or more sacrificial layers are different.

In some implementations, the electromechanical systems device layers (such as layers 430 and 440 in FIG. 4) can be arranged in a plurality of layers, such as one to ten layers of materials. In various implementations, each layer of the electromechanical systems device can include different materials, whereas in other implementations, the layers can include the same materials. In another implementation, alternating layers may include the same electromechanical systems device material. In some implementations, the electromechanical systems device layer materials include one or more of the following: gold (Au), platinum (Pt), silver (Ag), Al, nickel (Ni), Cr, Ti, palladium (Pd) and/or similar conductive materials and alloys thereof.

Deposition of the electromechanical systems device layer materials may be carried out using deposition techniques such as physical vapor deposition (PVD, e.g., sputtering), plasma-enhanced chemical vapor deposition (PECVD), thermal chemical vapor deposition (thermal CVD), atomic layer deposition (ALD), lamination or spin-coating.

In some implementations, the thicknesses of the electromechanical systems device layers are about 10 Å to about 100 μm. For example, the thickness of the electromechanical systems device layers can be about 10 Å to about 75 μm, about 5 nm to about 50 μm, about 10 nm to about 1 μm, about 10 nm to about 500 nm, about 50 nm to about 250 nm, about 75 nm to about 150 nm, about 100 nm to about 125 nm, around 10 Å, around 1 μm or around 100 μm.

Hermeticity layer (such as hermiticity layer 450 in FIG. 4) materials include any materials that can reduce the infusion of gases into the device. In some implementations, the hermeticity layer materials are based on a metal material. In some implementations, the hermeticity layer materials include metals such as Au, Pt, Ag, Ni, Cr, Ti, Pd, copper (Cu) and/or Al. In some implementations, the hermeticity layer materials are one or more of the following: oxides, nitrides, oxynitrides, metal oxides, metal, metal alloys or similar materials. In some implementations, the hermeticity layer material is silicon oxide. In some implementations, the hermeticity layer includes more than one sub-layer of hermeticity layer materials.

Deposition of the hermeticity layer materials may be carried out using deposition techniques such as physical vapor deposition (PVD or sputtering), plasma-enhanced chemical vapor deposition (PECVD), thermal chemical vapor deposition (thermal CVD), atomic layer deposition (ALD), lamination or spin-coating.

In some implementations, the thicknesses of the hermeticity layer can be about 100 Å to about 100 μm. For example, the thickness of the hermeticity layer can be about 100 Å to about 75 μm, about 10 Å to about 50 μm, about 10 nm to about 1 μm, about 10 nm to about 500 nm, about 50 nm to about 250 nm, about 75 nm to about 150 nm, about 100 nm to about 125 nm, around 100 Å, around 1 μm or around 100 μm.

Sealant materials (such as sealant material 460 of FIG. 4) include any materials that can interact with hermeticity layer materials to reduce the infusion of gases into the device. In some implementations, the sealant material is a metal-containing material. For example, the sealant material can include metals such as Au, Pt, Ag, Ni, Cr, Ti, Pd, Cu and/or Al. In some implementations, the sealant material is an oxide. In some implementations, the sealant material is one or more of the following: polymer, oxides, nitrides, oxynitrides, metal oxides, metal, metal alloys or similar materials. In some implementations, the sealant materials are silicon nitride and alumina deposited by ALD and combinations of silicon nitride and ALD-deposited alumina. In some implementations, the sealant materials include one or more layers of sealant materials.

Sealant materials may be the same or different than the hermeticity layer materials. As a non-limiting example, if the hermiticity layer material is Ti, then the sealant material can be Ti, thereby resulting in the same material for the sealant material and the hermiticity layer material. Alternatively, the sealant material can be Cr, Cu and/or Al, thereby resulting in the sealant material and the hermeticity layer material being different materials.

Deposition of the sealant material may be carried out using deposition techniques such as physical vapor deposition (PVD), e.g., sputtering, plasma-enhanced chemical vapor deposition (PECVD), thermal chemical vapor deposition (thermal CVD), ALD, lamination or spin-coating. A person of ordinary skill in the art will readily understand that the choice of a sealing process can depend upon the location of the gap to be sealed.

In some implementations, the thicknesses of the sealant material can be about 100 Å to about 100 μm. For example, the thickness of the sealant material can be about 100 Å to about 75 μm, about 10 Å to about 50 μm, about 10 nm to about 1 μm, about 10 nm to about 500 nm, about 50 nm to about 250 nm, about 75 nm to about 150 nm, about 100 nm to about 125 nm, around 100 Å, around 1 μm or around 100 μm.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the MEMS device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of manufacturing an electromechanical systems device, comprising:
providing a substrate having a getter layer; and
forming the electromechanical systems device above the getter layer, wherein the electromechanical systems device has an internal cavity exposed to the getter layer.

2. The method of claim 1, wherein the electromechanical systems device has a movable layer within the internal cavity.

3. The method of claim 1, wherein the getter layer includes at least one of lanthanum, titanium, zirconium, niobium, tantalum, vanadium, aluminum or alloys thereof.

4. The method of claim 1, wherein forming the electromechanical systems device above the getter layer further includes:
depositing a first sacrificial layer on the getter layer; and
removing a portion of the first sacrificial layer to expose the getter layer.

5. The method of claim 4, wherein the getter layer is deposited on the substrate and the deposition of the getter layer and the first sacrificial layer is conducted in situ.

6. The method of claim 5, wherein the deposition of the getter layer and the first sacrificial layer uses a technique independently selected from the group consisting of physical vapor deposition, plasma-enhanced chemical vapor deposition, thermal chemical vapor deposition, atomic layer deposition or spin-coating.

7. An electromechanical system device package, comprising:
a substrate;
at least one electromechanical systems device disposed on the substrate, wherein the at least one device has an internal cavity; and
a thin film getter disposed within the internal cavity.

8. The device package of claim 7, wherein the getter contacts the substrate within the internal cavity.

9. The device package of claim 7, wherein the electromechanical systems device is capable of moving within the internal cavity.

10. The device package of claim 7, wherein the getter includes at least one of lanthanum, titanium, zirconium, niobium, tantalum, vanadium, aluminum or alloys thereof.

11. The device package of claim 7, further including a hermeticity layer surrounding the at least one electromechanical systems device.

12. The device package of claim 11, wherein the at least one electromechanical systems device includes a movable layer that is suspended in the internal cavity between the getter and the hermeticity layer.

13. The device package of claim 12, wherein the movable layer is configured to contact a conductor upon the application of a voltage.

14. An electromechanical systems device, comprising:
a substrate;
a means for absorbing water vapor or environmental gases, the absorbing means being in contact with the substrate; and
one or more electromechanical systems device layers deposited above the substrate, wherein the electromechanical systems device layers form a cavity that is exposed to the absorbing means.

15. The electromechanical systems device of claim 14, wherein the absorbing means includes a thin film getter.

16. The electromechanical systems device of claim 15, further including a hermeticity layer contacting a portion of at least one of the one or more electromechanical systems device layers.

17. The electromechanical systems device of claim 16, wherein the one or more electromechanical systems device layers include one or more movable layers that are suspended in the cavity between the thin film getter and the hermeticity layer.
